(19) United States
(12) Patent Application Publication
(10) Pub. No.: US 2024/0339447 A1
(43) Pub. Date: Oct. 10, 2024

(54) ELECTROSTATIC DISCHARGE PROTECTION DEVICE

(71) Applicant: MEDIATEK INC., Hsinchu City (TW)

(72) Inventors: Tzung-Lin LI, Hsinchu City (TW); Yuan-Fu CHUNG, Hsinchu City (TW); Tung-Hsing LEE, Hsinchu City (TW)

(21) Appl. No.: 18/603,426

(22) Filed: Mar. 13, 2024

Related U.S. Application Data
(60) Provisional application No. 63/495,130, filed on Apr. 10, 2023.

(51) Int. Cl. H01L 27/02; H01L 29/868

(52) U.S. Cl. CPC H01L 27/0255; H01L 29/868

(57) ABSTRACT

An electrostatic discharge protection device is provided. The electrostatic discharge protection device includes a P-type semiconductor substrate, P-type and N-type well regions, a deep N-type well region, first N-type and P-type doped regions, second N-type and P-type doped regions. The P-type and N-type well regions are located in the P-type semiconductor substrate. The deep N-type well region is located in the P-type semiconductor substrate and below the P-type well region. The first N-type and P-type doped regions are located on the P-type well region. The second N-type and P-type doped regions are located on the N-type well region. The first P-type doped region is electrically connected to the second N-type doped region.

### CROSS REFERENCE TO RELATED APPLICATIONS

This application claims the benefit of U.S. Provisional Application No. 63/495,130, filed Apr. 10, 2023, the entirety of which is incorporated by reference herein.

### BACKGROUND OF THE INVENTION

### Field of the Invention

The present disclosure relates to an electrostatic discharge protection device, and, in particular, to the structure of an electrostatic discharge protection device for application in high-frequency circuits.

### Description of the Related Art

Electrostatic discharge (ESD) is a phenomenon in which a charge is released and transferred between a semiconductor device (e.g., a semiconductor chip) and an external object (e.g., a human body). In an ESD, a large amount of charge is released in a short time, and so the energy from the ESD is much higher than the bearing capacity of the semiconductor device, which may result in a temporary functional failure or even permanent damage to the semiconductor device. Therefore, an ESD clamp circuit is built into semiconductor devices to offer an electrostatic discharge path that effectively protects the semiconductor device, so that the reliability and service life of the semiconductor device is maintained. In a high-frequency circuit, however, the parasitic capacitors used in conventional ESD protection circuits (which use diodes) may cause the RF circuits and high-speed circuits to suffer from poor electrical performance.

### BRIEF SUMMARY OF THE INVENTION

An embodiment of the disclosure provides an electrostatic discharge protection device. The electrostatic discharge protection device includes a P-type semiconductor substrate, a P-type well region, a deep N-type well region, a first N-type doped region, a first P-type doped region, an N-type well region, a second N-type doped region and a second P-type doped region. The P-type well region is located in the P-type semiconductor substrate. The deep N-type well region is located in the P-type semiconductor substrate and below the P-type well region. The first N-type doped region is located on the P-type well region. The first P-type doped region is located on the deep N-type well region. The first N-type doped region and the first P-type doped region are arranged side-by-side and spaced apart from each other. The N-type well region is located in the P-type semiconductor substrate. The second N-type doped region is located on the N-type well region. The second P-type doped region is located on the N-type well region. The second N-type doped region and the second P-type doped region are arranged side-by-side and spaced apart from each other. The first P-type doped region is electrically connected to the second N-type doped region.

An embodiment of the disclosure provides an electrostatic discharge protection device. The electrostatic discharge protection device includes a P-type semiconductor substrate, a P-type well region, an N-type heavily doped region, a P-type doped region, a first P-type heavily doped region, a deep N-type well region, an N-type well region, a second N-type heavily doped region and a second P-type heavily doped region. The P-type well region has a first doping concentration located in the P-type semiconductor substrate. The N-type heavily doped region is located on the P-type well region. The P-type doped region having a second doping concentration is located in the P-type semiconductor substrate. The P-type well region and the P-type doped region are adjacent to each other. The first P-type heavily doped region is located on the P-type doped region. The first N-type heavily doped region and the first P-type heavily doped region are arranged side-by-side and spaced apart from each other. The deep N-type well region is located in the P-type semiconductor substrate and below the P-type first well region and the P-type doped region. The N-type well region is located in the P-type semiconductor substrate. The second N-type heavily doped region is located on the N-type well region. The second P-type heavily doped region is located on the N-type well region. The second N-type heavily doped region and the second P-type heavily doped region are arranged side-by-side and spaced apart from each other. The first P-type heavily doped region is electrically connected to the second N-type heavily doped region.

### BRIEF DESCRIPTION OF THE DRAWINGS

The present invention can be more fully understood by reading the subsequent detailed description and examples with references made to the accompanying drawings, wherein:

FIG. 1 is a schematic connection diagram of an electrostatic discharge protection device in accordance with some embodiments of the disclosure;

FIG. 2 is a schematic cross-sectional view of the electrostatic discharge protection device of FIG. 1 in accordance with some embodiments of the disclosure;

FIG. 3 shows an equivalent discharge circuit diagram of the ESD protection device of FIG. 2 when an electrostatic discharge (ESD) event occurs between the input/output terminal IO and the power supply terminal VDD or between the ground terminal VSS and the input/output terminal IO;

FIG. 4 is a schematic cross-sectional view of the electrostatic discharge protection device of FIG. 1 in accordance with some embodiments of the disclosure; and

FIG. 5 shows an equivalent discharge circuit diagram of the ESD protection device of FIG. 4 when an electrostatic discharge (ESD) event occurs between the input/output terminal IO and the power supply terminal VDD or between the ground terminal VSS and the input/output terminal IO.

### DETAILED DESCRIPTION OF THE INVENTION

The following description is made for the purpose of illustrating the general principles of the invention and should not be taken in a limiting sense. The scope of the invention is best determined by reference to the appended claims.

Electrostatic discharge (ESD) devices arranged between the input/output (IO) pad and the internal circuit are usually provided to protect the internal circuit. One kind of the current ESD devices is composed of diodes formed by sharing the low voltage P-type well region/N-type well region of the metal-oxide-semiconductor (MOS) device of the internal circuit. In the high-frequency circuit applications, however, the parasitic capacitance of the ESD device may cause increased signal loss, thereby affecting the performance of the internal circuit.

To solve the aforementioned problem, one approach is to form the ESD device including two or more diodes connected in series in order to reduce the total capacitance of the parasitic capacitors of the ESD device. When the internal circuit is operating normally, however, the approach results in higher on-resistance (Ron). According to the high-frequency circuit application requirements, it is becoming increasingly necessary to provide an ESD device with less parasitic capacitance and on-resistance (Ron).

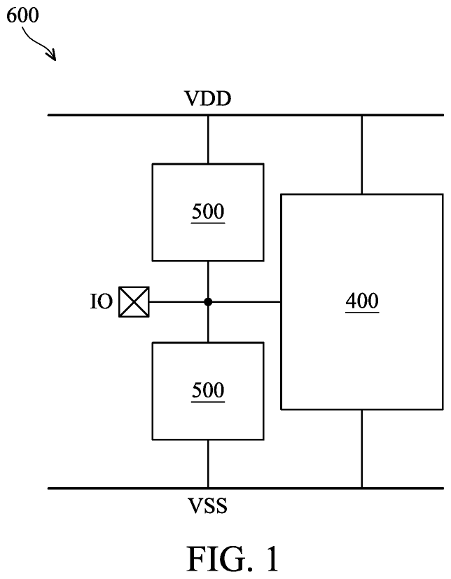

FIG. 1 is a schematic connection diagram of an electrostatic discharge (ESD) protection device 500 (including ESD protection devices 500A and 500B shown in the following figures) disposed in a system 600 in accordance with some embodiments of the disclosure. The system 600 includes an internal circuit 400 and the electrostatic discharge (ESD) protection device 500 used to protect the internal circuit 400. The internal circuit 400 is electrically connected to an input/output terminal IO, a power supply terminal VDD and a ground terminal VSS of the system 600. In some embodiments, the ESD protection device 500 is electrically connected between the input/output terminal IO and the power supply terminal VDD of the system 600 to prevent an electrostatic discharge current from flowing through the internal circuit 400. In addition, the ESD protection device 500 is electrically connected between the input/output terminal IO and the ground terminal VSS of the system 600 to prevent an electrostatic discharge current from flowing through the internal circuit 400.

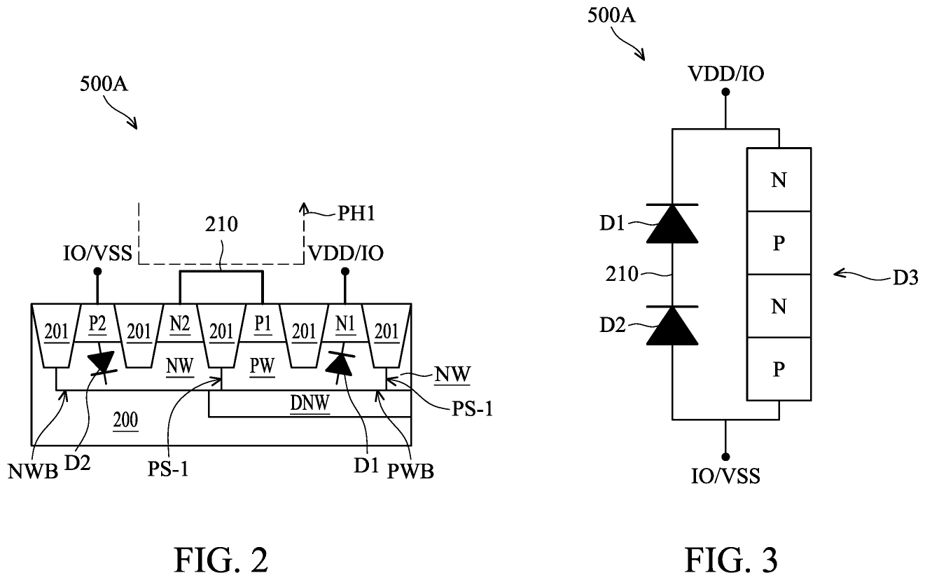

FIG. 2 is a schematic cross-sectional view of the ESD protection device 500A of FIG. 1 in accordance with some embodiments of the disclosure. The ESD protection device 500A includes a P-type semiconductor substrate 200, a P-type well region PW, a deep N-type well region DNW, a first N-type doped region N1, a first P-type doped region P1, an N-type well region NW, a second N-type doped region N2 and a second P-type doped region P2. The N-type well region NW and the P-type well region PW are located in the P-type semiconductor substrate 200. The N-type well region NW and the P-type well region PW may be adjacent to each other. In some embodiments, the N-type well region NW surrounds and is in contact with opposite sidewalls PS-1 of the P-type well region PW. Therefore, the sidewalls PS-1 of the P-type well region PW may also serve as interfaces PS-1 between the N-type well region NW and the P-type well region PW.

The deep N-type well region DNW is located in the P-type semiconductor substrate 200. In addition, the deep N-type well region DNW is below the N-type well region NW and the P-type first well region PW. Furthermore, the deep N-type well region DNW is in contact with a bottom PWB of the P-type well region PW and a bottom NWB of the N-type well region NW. Therefore, the N-type well region NW and deep N-type well region DNW. As shown in FIG. 2, a sidewall (also located at the sidewall PS-1 of the P-type well region PW) and the bottom NWB of the N-type well region NW are in contact with the P-type well region PW and the deep N-type well region DNW. In some embodiments, the interfaces PS-1 between the N-type well region NW and the P-type well region PW are directly above the deep N-type well region DNW.

Each of the N-type well region NW and the P-type well region PW has at least a heavily doped region formed thereon. For example, the first N-type doped region N1 (i.e., a first N-type heavily doped region N1) and the first P-type doped region P1 (i.e., a first P-type heavily doped region P1) are located directly on different portions of the P-type well region PW. In other words, the first N-type doped region N1 is located directly on the P-type well region PW, and the first P-type doped region P1 is located directly on a P-type doped region (not shown) formed of a portion of the P-type well region PW (i.e., the P-type doped region and the P-type well region PW have the same doping concentration). In addition, the first N-type doped region N1 and the first P-type doped region P1 are located on the deep N-type well region DNW. The second N-type doped region N2 (i.e., a second N-type heavily doped region N2) and the second P-type doped region P1 (i.e., a first P-type heavily doped region P2) are located on the N-type well region NW. In some embodiments, the first N-type doped region N1 and the second N-type doped region N2 may have the same doping concentration. The first P-type doped region P1 and the second P-type doped region P2 may have the same doping concentration.

The first N-type doped region N1 and the first P-type doped region P1 may be arranged side-by-side and spaced apart from each other by an isolation feature 201 such as a shallow trench isolation trench isolation (STI) in the P-type well region PW. In addition, the first N-type doped region N1 and the first P-type doped region P1 may be separated from the deep N-type well region DNW by the P-type well region PW. The first P-type doped region P1 and the second N-type doped region N2 may be arranged side-by-side and spaced apart from each other by the isolation feature 201 between the P-type well region PW and the N-type well region NW. In addition, the second N-type doped region N2 and the second P-type doped region P2 may be arranged side-by-side and spaced apart from each other by the isolation feature 201 in the N-type well region NW.

In some embodiments in which the ESD protection device 500A is electrically connected between the input/output terminal IO and the power supply terminal VDD, the first N-type doped region N1 is electrically connected to the power supply terminal VDD. The first P-type doped region P1 is electrically connected to the second N-type doped region N2 directly by a conductive line 210 (i.e., two terminals of the conductive line 210 are in contact with the first P-type doped region P1 and the second N-type doped region N2). In addition, the second P-type doped region P2 is electrically connected to the input/output terminal IO. In some embodiments in which the ESD protection device 500A is electrically connected between the input/output terminal IO and the ground terminal VSS. The first N-type doped region N1 is electrically connected to the input/output terminal IO. The first P-type doped region P1 is electrically connected to the second N-type doped region N2 directly by the conductive line 210. In addition, the second P-type doped region P2 is electrically connected to the ground terminal VSS.

FIG. 3 also shows an equivalent discharge circuit diagram of the ESD protection device 500A when an electrostatic discharge (ESD) event occurs between the input/output terminal IO and the power supply terminal VDD or between the ground terminal VSS and the input/output terminal IO. Furthermore, FIG. 2 shows parasitic elements of the equivalent discharge circuit of FIG. 3 at the corresponding positions of the ESD protection device 500A. As shown in FIGS. 2 and 3, the P-type well region PW and the first N-type doped region N1 form a first parasitic diode D1. The second P-type doped region P2 and the N-type well region NW form a second parasitic diode D2. In some embodiments, the first parasitic diode D1 and the second parasitic diode D2 are connected in series by the first P-type doped region P1, the second N-type doped region N2 and the conductive line 210. The anode (the P-type well region PW) of the first parasitic diode D1 is electrically connected to the cathode (the N-type well region NW) of the second parasitic diode D2. In addition, the second P-type doped region P2, the N-type well region NW, the P-type well region PW and the first N-type doped region N1 may collectively form a parasitic PNPN diode D3. The parasitic PNPN diode D3 is connected in parallel to the first parasitic diode D1 and the second parasitic diode D2 that are connected in series. Compared to a conventional ESD protection device, the ESD protection device 500A may have reduced parasitic resistance.

When an electrostatic discharge event occurs between the input/output terminal IO and the power supply terminal VDD, the first parasitic diode D1 and the second parasitic diode D2 connected in series are triggered to ON (turned-on). In addition, the parasitic PNPN diode is triggered to ON. Therefore, a current path PH1 from the input/output terminal IO to the power supply terminal VDD is formed to discharge the electrostatic charges away from the internal circuit 400.

Similarly, when an electrostatic discharge event occurs between the ground terminal VSS and the input/output terminal IO, the first parasitic diode D1 and the second parasitic diode D2 connected in series are triggered to ON (turned-on) In addition, the parasitic PNPN diode is triggered to ON. Therefore, the current path PH1 from the ground terminal VSS to the input/output terminal IO to discharge the electrostatic charges away from the internal circuit 400.

When an electrostatic discharge (ESD) event occurs between the input/output terminal IO and the power supply terminal VDD or between the ground terminal VSS and the input/output terminal IO, the discharge current may flow through not only the first parasitic diode D1 and the second parasitic diode D2, but also the parasitic PNPN diode D3.

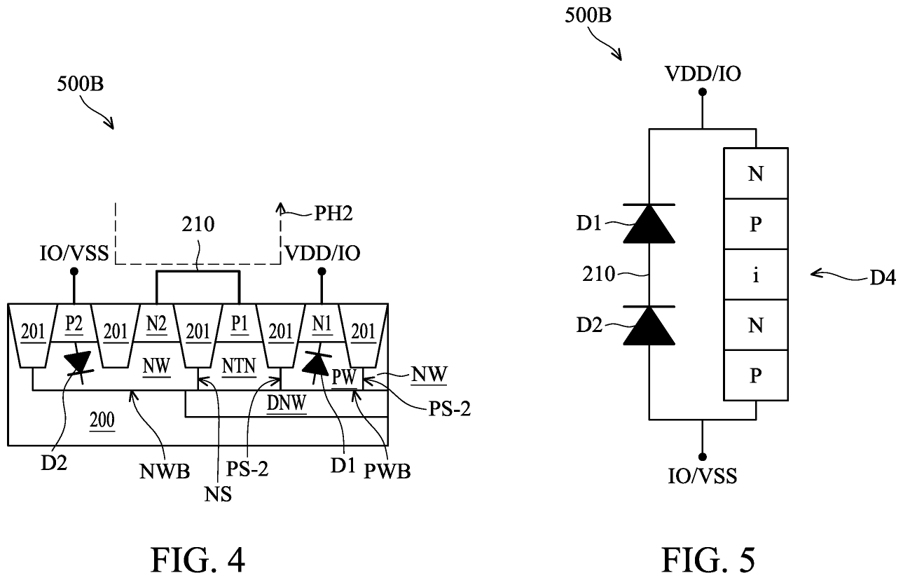

FIG. 4 is a schematic cross-sectional view of the ESD protection device 500B of FIG. 1 in accordance with some embodiments of the disclosure. Elements of the embodiments hereinafter, that are the same or similar as those previously described with reference to FIGS. 1 to 3, are not repeated for brevity. As shown in FIG. 4, the difference between the ESD protection device 500A and the ESD protection device 500B is that the ESD protection device 500B further includes a P-type intrinsic doped region NTN. The first P-type doped region P1 of the ESD protection device 500B is located directly on the P-type intrinsic doped region NTN (also serves as a kind of a P-type doped region) surrounded by the N-type well region NW, the deep N-type well region DNW and the P-type well region PW. The P-type well region PW may be located directly below the first N-type doped region N1 without extending below the first P-type doped region P1. In some embodiments, the first P-type doped region P1 is separated from the N-type well region NW, the deep N-type well region DNW and the P-type well region PW by the P-type intrinsic doped region NTN. In addition, the P-type well region PW may be separated from the N-type well region NW by the P-type intrinsic doped region NTN. As shown in FIG. 4, an interface NS (also serve as a sidewall NS of the N-type well region NW close to the P-type intrinsic doped region NTN) between the P-type intrinsic doped region NTN and the N-type well region NW and an interface PS-2 (also serve as a sidewall PS-2 of the P-type well region PW close to the P-type intrinsic doped region NTN) between the P-type intrinsic doped region NTN and the P-type well region PW are directly above the deep N-type well region DNW.

In some embodiments, the doping concentration of the P-type well region PW is higher than the doping concentration of the P-type intrinsic doped region NTN. In some embodiments, the second doping concentration of the P-type intrinsic doped region NTN is equal to the doping concentration of the P-type semiconductor substrate 200.

In some embodiments in which the ESD protection device 500B is electrically connected between the input/output terminal IO and the power supply terminal VDD, the first N-type doped region N1 is electrically connected to the power supply terminal VDD. The first P-type doped region P1 is electrically connected to the second N-type doped region N2 directly by the conductive line 210. In addition, the second P-type doped region P2 is electrically connected to the input/output terminal IO. In some embodiments in which the ESD protection device 500B is electrically connected between the input/output terminal IO and the ground terminal VSS. The first N-type doped region N1 is electrically connected to the input/output terminal IO. The first P-type doped region P1 is electrically connected to the second N-type doped region N2 directly by the conductive line 210. In addition, the second P-type doped region P2 is electrically connected to the ground terminal VSS.

FIG. 5 also shows an equivalent discharge circuit diagram of the ESD protection device 500B when an electrostatic discharge (ESD) event occurs between the input/output terminal IO and the power supply terminal VDD or between the ground terminal VSS and the input/output terminal IO. Furthermore, FIG. 4 shows parasitic elements of the equivalent discharge circuit of FIG. 5 at the corresponding positions of the ESD protection device 500B. As shown in FIGS. 4 and 5, the P-type well region PW and the first N-type doped region N1 form the first parasitic diode D1. The second P-type doped region P2 and the N-type well region NW form the second parasitic diode D2. In some embodiments, the first parasitic diode D1 and the second parasitic diode D2 are connected in series by the P-type intrinsic doped region NIN, the first P-type doped region P1, the second N-type doped region N2 and the conductive line 210. The anode (the P-type well region PW) of the first parasitic diode D1 may be electrically connected to the cathode (the N-type well region NW) of the second parasitic diode D2. In some embodiments, the P-type well region PW, the P-type intrinsic doped region NIN and the N-type well region NW form a parasitic PIN diode D4-1. In addition, the second P-type doped region P2, the N-type well region NW, the P-type intrinsic doped region NIN, the P-type well region PW and the first N-type doped region N1 may collectively form a parasitic PN-i-PN diode D4. The parasitic PN-i-PN diode D4 is connected in parallel to the first parasitic diode D1 and the second parasitic diode D2 that are connected in series. Compared to a conventional ESD protection device, the parasitic PN-i-PN diode D4 may have a reduced parasitic capacitance (i.e., the depletion capacitance) due to a larger depletion region at the P-type intrinsic doped region NIN. Therefore, the ESD protection device 500B may have less parasitic resistance and less parasitic capacitance.

When an electrostatic discharge event occurs between the input/output terminal IO and the power supply terminal VDD, the first parasitic diode D1 and the second parasitic diode D2 connected in series are triggered to ON (turned-on). In addition, the PN-i-PN diode is triggered to ON. Therefore, a current path PH2 from the input/output terminal IO to the power supply terminal VDD is formed to discharge the electrostatic charges away from the internal circuit 400.

When the internal circuits 400 are operating normally (no electrostatic discharge event occurs), the PN junction of the parasitic PIN diode D4-1 may be in reverse bias condition and form a parasitic capacitor (not shown). Since the P-type intrinsic doped region NIN is lower than the P-type well region PW. The parasitic capacitor may have lower parasitic capacitance (i.e., the depletion capacitance). Therefore, the electrostatic discharge (ESD) protection device 500B may have a reduced signal loss in high-speed application.

Similarly, when an electrostatic discharge event occurs between the ground terminal VSS and the input/output terminal IO, the first parasitic diode D1 and the second parasitic diode D2 connected in series are triggered to ON (turned-on). In addition, the PN-i-PN diode is triggered to ON. Therefore, the current path PH2 from the ground terminal VSS to the input/output terminal IO to discharge the electrostatic charges away from the internal circuit 400.

When an electrostatic discharge (ESD) event occurs between the input/output terminal IO and the power supply terminal VDD or between the ground terminal VSS and the input/output terminal IO, the discharge current may flow through not only the first parasitic diode D1 and the second parasitic diode D2, but also the parasitic PN-i-PN diode D4.

In some embodiments, the electrostatic discharge (ESD) protection devices 500 that are electrically connected between the input/output terminal IO and the power supply terminal VDD and between the input/output terminal IO and the ground terminal VSS of the system 600 (FIG. 1) may have various combinations. For example, the system 600 may include the electrostatic discharge (ESD) protection device 500A that is electrically connected between the input/output terminal IO and the power supply terminal VDD and the electrostatic discharge (ESD) protection device 500B that is electrically connected between the input/output terminal IO and the ground terminal VSS. For example, the system 600 may include the electrostatic discharge (ESD) protection device 500B that is electrically connected between the input/output terminal IO and the power supply terminal VDD and the electrostatic discharge (ESD) protection device 500A that is electrically connected between the input/output terminal IO and the ground terminal VSS.

Embodiments provide an electrostatic discharge (ESD) protection device. The ESD protection device can discharge the electrostatic charges away from the internal circuits when the electrostatic discharge events occurs between the terminals of the input/output terminal IO and the power supply terminal VDD, or between the terminals of the ground terminal VSS and the input/output terminal IO. The ESD protection device includes a P-type semiconductor substrate, adjacent P-type and N-type well regions, a deep N-type well region below the P-type first well region, first N-type and P-type doped regions on the P-type well region and the deep N-type well region, second N-type and P-type doped regions on the N-type well region. The first P-type doped region is electrically connected to the second N-type doped region directly by a conductive line. In some embodiments, the first N-type doped region is electrically connected to an input/output terminal IO, and the second P-type doped region is electrically connected to a ground terminal VSS. In some embodiments, the first N-type doped region is electrically connected to a power supply terminal VDD, and the second P-type doped region is electrically connected to an input/output terminal IO. In the ESD protection device, the P-type well region and the first N-type doped region form a first parasitic diode, and the second P-type doped region and the N-type well region form a second parasitic diode. The first parasitic diode and the second parasitic diode are connected in series by the first P-type doped region and the second N-type doped region.

In some embodiments, the first N-type and P-type doped regions of the ESD protection device are located directly on the P-type well region. The second P-type doped region, the N-type well region, the P-type well region and the first N-type doped region may form a parasitic PNPN diode. The parasitic PNPN diode may be connected in parallel to the series-connected first parasitic diode and the second parasitic diode. When an electrostatic discharge event occurs between the input/output terminal IO and the power supply terminal VDD or between the ground terminal VSS and the input/output terminal IO, the discharge current may flow through not only the first and second parasitic diodes, but also the parasitic PNPN diode. In addition, the ESD protection device composed of the first and second parasitic diodes and the parasitic PNPN diode may have less on-resistance (Ron) during normal operation.

In some embodiments, the first P-type doped region is located directly on a P-type intrinsic doped region. In addition, the first N-type doped region is located directly on the P-type well region adjacent to the P-type intrinsic doped region. In addition, the P-type intrinsic doped region is surrounded by the N-type well region, the deep N-type well region and the P-type well region. The second P-type doped region, the N-type well region, the P-type intrinsic doped region, the P-type well region and the first N-type doped region form a parasitic PN-i-PN diode. The parasitic PN-i-PN diode having reduced parasitic capacitance (i.e., the depletion capacitance) is connected in parallel to the series-connected first parasitic diode and the second parasitic diode. When an electrostatic discharge event occurs between the input/output terminal IO and the power supply terminal VDD or between the ground terminal VSS and the input/output terminal IO, the discharge current may flow through not only the first and second parasitic diodes, but also the parasitic PN-i-PN diode. In addition, the ESD protection device composed of the first and second parasitic diodes and the parasitic PN-i-PN diode may have less parasitic capacitance and on-resistance (Ron) during normal operation.

Therefore, the electrostatic discharge (ESD) protection device may have a reduced signal loss in high-speed application.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electrostatic discharge protection device, comprising:
a P-type semiconductor substrate;
a P-type well region located in the P-type semiconductor substrate;
a deep N-type well region located in the P-type semiconductor substrate and below the P-type well region;
a first N-type doped region located on the P-type well region;
a first P-type doped region located on the deep N-type well region, wherein the first N-type doped region and the first P-type doped region are arranged side-by-side and spaced apart from each other;
an N-type well region located in the P-type semiconductor substrate;
a second N-type doped region located on the N-type well region; and
a second P-type doped region located on the N-type well region, wherein the second N-type doped region and the second P-type doped region are arranged side-by-side and spaced apart from each other,
wherein the first P-type doped region is electrically connected to the second N-type doped region.

2. The electrostatic discharge protection device as claimed in claim 1, wherein the first N-type doped region is electrically connected to an input/output terminal, and the second P-type doped region is electrically connected to a ground terminal.

3. The electrostatic discharge protection device as claimed in claim 1, wherein the first N-type doped region is electrically connected to a power supply terminal, and the second P-type doped region is electrically connected to an input/output terminal.

4. The electrostatic discharge protection device as claimed in claim 1, wherein the P-type well region and the first N-type doped region form a first parasitic diode, and the second P-type doped region and the N-type well region form a second parasitic diode, and wherein the first parasitic diode and the second parasitic diode are connected in series by the first P-type doped region and the second N-type doped region.

5. The electrostatic discharge protection device as claimed in claim 4, wherein the N-type well region surrounds sidewalls of the P-type well region, and the deep N-type well region is in contact with bottoms of the P-type well region and the N-type well region.

6. The electrostatic discharge protection device as claimed in claim 5, wherein the first P-type doped region is located directly on the P-type well region.

7. The electrostatic discharge protection device as claimed in claim 6, wherein the first P-type doped region is separated from the deep N-type well region by the P-type well region.

8. The electrostatic discharge protection device as claimed in claim 6, wherein the N-type well region is in contact with the P-type well region and the deep N-type well region.

9. The electrostatic discharge protection device as claimed in claim 6, wherein an interface between the N-type well region and the P-type well region is directly above the deep N-type well region.

10. The electrostatic discharge protection device as claimed in claim 6, wherein the second P-type doped region, the N-type well region, the P-type well region and the first N-type doped region form a parasitic PNPN diode, and wherein the parasitic PNPN diode is connected in parallel to the series-connected first parasitic diode and the second parasitic diode.

11. The electrostatic discharge protection device as claimed in claim 5, wherein the first P-type doped region is located directly on a P-type intrinsic doped region surrounded by the N-type well region, the deep N-type well region and the P-type well region.

12. The electrostatic discharge protection device as claimed in claim 11, wherein the first P-type doped region is separated from the deep N-type well region and the P-type well region by the P-type intrinsic doped region.

13. The electrostatic discharge protection device as claimed in claim 11, wherein the P-type well region is separated from the N-type well region by the P-type intrinsic doped region.

14. The electrostatic discharge protection device as claimed in claim 11, wherein a first interface between the P-type intrinsic doped region and the N-type well region and a second interface between the P-type intrinsic doped region and the P-type well region are directly above the deep N-type well region.

15. The electrostatic discharge protection device as claimed in claim 11, wherein a first doping concentration of the P-type well region is higher than a second doping concentration of the P-type intrinsic doped region.

16. The electrostatic discharge protection device as claimed in claim 15, wherein the second doping concentration of the P-type intrinsic doped region is equal to a third doping concentration of the P-type semiconductor substrate.

17. The electrostatic discharge protection device as claimed in claim 11, wherein the P-type well region, the P-type intrinsic doped region and the N-type well region form a parasitic PIN diode.

18. The electrostatic discharge protection device as claimed in claim 17, wherein the second P-type doped region, the N-type well region, the P-type intrinsic doped region, the P-type well region and the first N-type doped region form a parasitic PN-i-PN diode, and wherein the parasitic PN-i-PN diode is connected in parallel to the series-connected first parasitic diode and the second parasitic diode.

19. An electrostatic discharge protection device, comprising:
a P-type semiconductor substrate;
a P-type well region having a first doping concentration located in the P-type semiconductor substrate;
an N-type heavily doped region located on the P-type well region;
a P-type doped region having a second doping concentration located in the P-type semiconductor substrate, wherein the P-type well region and the P-type doped region are adjacent to each other;
a first P-type heavily doped region located on the P-type doped region, wherein the first N-type heavily doped region and the first P-type heavily doped region are arranged side-by-side and spaced apart from each other;
a deep N-type well region located in the P-type semiconductor substrate and below the P-type first well region and the P-type doped region;
an N-type well region located in the P-type semiconductor substrate;
a second N-type heavily doped region located on the N-type well region; and
a second P-type heavily doped region located on the N-type well region, wherein the second N-type heavily doped region and the second P-type heavily doped region are arranged side-by-side and spaced apart from each other,
wherein the first P-type heavily doped region is electrically connected to the second N-type heavily doped region.

20. The electrostatic discharge protection device as claimed in claim 19, wherein the first N-type heavily doped region is electrically connected to an input/output terminal, and the second P-type heavily doped region is electrically connected to a ground terminal.

21. The electrostatic discharge protection device as claimed in claim 19, wherein the first N-type heavily doped region is electrically connected to a power supply terminal, and the second P-type heavily doped region is electrically connected to an input/output terminal.

22. The electrostatic discharge protection device as claimed in claim 19, wherein the first doping concentration is equal to the second doping concentration.

23. The electrostatic discharge protection device as claimed in claim 22, wherein the second P-type doped region, the N-type well region, the P-type doped region, the P-type well region and the first N-type doped region form a parasitic PNPN diode.

24. The electrostatic discharge protection device as claimed in claim 19, wherein the first doping concentration is higher than the second doping concentration, and wherein the second doping concentration is equal to a third doping concentration of the P-type semiconductor substrate.

25. The electrostatic discharge protection device as claimed in claim 24, wherein the second P-type doped region, the N-type well region, the P-type doped region, the P-type well region and the first N-type doped region form a parasitic PN-i-PN diode.
